(19) United States
(12) Patent Application Publication
(10) Pub. No.: US 2025/0155475 A1
(43) Pub. Date: May 15, 2025

(54) ELECTRICAL SENSOR ASSEMBLY

(71) Applicant: G & W Electric Company, Bolingbrook, IL (US)

(72) Inventor: Alberto Bauer, Al Menara (AE)

(21) Appl. No.: 19/020,040

(22) Filed: Jan. 14, 2025

Related U.S. Application Data
(63) Continuation of application No. 18/313,799, filed on May 8, 2023, now Pat. No. 12,196,785.
Application No. 18/313,799 is a continuation of application No. 17/664,585, filed on May 23, 2022, now Pat. No. 11,644,484.
Application No. 17/664,585 is a continuation of application No. 17/414,887, filed on Jun. 16, 2021, now Pat. No. 11,340,266.

(30) Foreign Application Priority Data
Dec. 17, 2018 (IT) 102018000011146
Dec. 17, 2018 (IT) 202018000003942

(51) Int. Cl. G01R 15/16; G01R 19/00

(52) U.S. Cl. CPC G01R 15/165; G01R 19/0084; G01R 15/16; G01R 19/0092

(57) ABSTRACT

A sensor assembly includes an electrode, a tubular section, and a mass of dielectric material extending along a longitudinal axis, the tubular section at least partially surrounding and radially spaced from the electrode. The tubular section includes a tubular support member comprising electrically insulating material, an inner electrically conductive material disposed on an inner surface of the support member, a first tubular electric screen disposed on an outer surface of the support member and electrically isolated from the inner electrically conductive material, and a second tubular electric screen extending in a direction along the longitudinal axis beyond an axial end of the tubular support member. The second tubular electric screen is electrically isolated from the inner electrically conductive material, and the mass of dielectric material at least partially encloses the electrode and the tubular support member, the inner electrically conductive material, and the first and second tubular electric screens.

### CROSS-REFERENCE TO RELATED APPLICATIONS

This application is a continuation of U.S. patent application Ser. No. 18/313,799, filed May 8, 2023, issued as U.S. Pat. No. 12,196,785, which is a continuation of U.S. patent application Ser. No. 17/664,585, filed May 23, 2022, issued as U.S. Pat. No. 11,644,484, which is a continuation of U.S. patent application Ser. No. 17/414,887, filed Jun. 16, 2021, issued as U.S. Pat. No. 11,340,266, which is a national stage application of International Patent Application No. PCT/US2019/066899, filed Dec. 17, 2019, which claims priority to Italian Patent Application No. 102018000011146, filed Dec. 17, 2018, and to Italian Utility Model application No. 202018000003942, filed Dec. 17, 2018, the entire contents of all of which are incorporated herein by reference.

### FIELD OF THE DISCLOSURE

The present disclosure relates to an electrical sensor assembly, preferably intended for electrical transformers, electrical cabinets and other similar structures, that enables the electric field generated by a live connecting bar to be detected, for example to detect the voltage value of said connecting bar in relation to the detected electric field.

More specifically, the present disclosure relates to a sensor assembly that is able to detect the electric field generated by the connecting bar without being influenced by any surrounding electrical fields, such as the fields generated by other conductors arranged nearby.

### BACKGROUND

Electrical sensor assemblies of the aforementioned type are known, but suffer from a series of drawbacks.

A first drawback is that said known sensor assemblies do not enable the electric field generated by the connecting bar to be detected without being influenced by other surrounding fields.

A second drawback is that said known sensor assemblies are somewhat large.

A third drawback is that said known sensor assemblies do not enable electrical fields and/or related magnitudes to be measured with sufficient accuracy.

A fourth drawback is that said known sensor assemblies are not immune to surrounding electrical fields generated, for example, by other conductors arranged nearby.

A fifth drawback is that said known sensor assemblies do not enable electrical fields and/or related magnitudes to be measured with sufficient accuracy in the presence of temperature variations.

A sixth drawback is that said known sensor assemblies do not retain over time the technical features required to perform the function of the sensor assembly and/or to maintain the required safety level (partial discharges, detachment, rapid ageing, etc.).

A seventh drawback is that said known sensor assemblies are complex and costly to make.

An eighth drawback is that, in said known sensor assemblies, the resin of dielectric material placed about the components of the sensor assembly have cavities (air bubbles), which results in unwanted partial discharging.

A ninth drawback is that, in said known sensor assemblies, said resin is detached from the elements that comprise the capacitive sensor, which results in unwanted partial discharging.

A tenth drawback is that, in said known sensor assemblies, said resin is not perfectly bonded and/or stuck and/or linked to the components that form the sensor assembly and consequently, ageing causes said resin to become detached from said members, which results in unwanted partial discharging. This drawback is particularly common where the sensor assembly is used in an environment in which the operating temperature (hot/cold) varies cyclically.

### SUMMARY

Sensor assemblies according to embodiments of the present disclosure may advantageously resolve one or more of the aforementioned drawbacks.

For example, the present disclosure provides, in one aspect, a sensor assembly including a connecting bar extending along a longitudinal axis and a tubular body extending along the longitudinal axis and at least partially surrounding the connecting bar such that the tubular body is radially spaced from the connecting bar. The tubular body includes a support member made of an insulating material. The support member includes an inner surface and an outer surface opposite the inner surface. The tubular body also includes a first section with an electric field sensor comprising a first layer of electrically conductive material disposed on the inner surface of the support member. The electric field sensor is configured to detect an electric field produced by the connecting bar. The first section also includes a first electric screen comprising a second layer of electrically conductive material disposed on the outer surface of the support member, and the first electric screen is configured to shield the electric field sensor from outside electrical interference. The tubular body also includes a second section disposed adjacent the first section along the longitudinal axis, the second section including a second electric screen. The sensor assembly further includes a dielectric material at least partially enclosing the tubular body.

The present disclosure provides, in another aspect, a sensor assembly including a connecting bar extending along a longitudinal axis and a tubular body extending along the longitudinal axis and at least partially surrounding the connecting bar such that the tubular body is radially spaced from the connecting bar. The tubular body includes a support member made of an insulating material, the support member including an inner surface, an outer surface opposite the inner surface, and a plurality of cantilevered tabs extending parallel to the longitudinal axis. The tubular body also includes an electric field sensor comprising a first layer of electrically conductive material disposed on the inner surface of the support member, the electric field sensor configured to detect an electric field produced by the connecting bar, and a first electric screen comprising a second layer of electrically conductive material disposed on the outer surface of the support member, the first electric screen configured to shield the electric field sensor from outside electrical interference. The sensor assembly also includes a dielectric material at least partially enclosing the tubular body. Adjacent tabs of the plurality of cantilevered tabs are circumferentially spaced in order to form axial through openings therebetween.

The present disclosure provides, in another aspect, a sensor assembly including a connecting bar extending along a longitudinal axis and a body extending along the longitudinal axis and at least partially surrounding the connecting bar such that the body is radially spaced from the connecting bar. The body includes a support member made of an insulating material, with an inner surface and an outer surface. The body also includes a first section having an electric field sensor comprising a first layer of electrically conductive material disposed on the inner surface of the support member, the electric field sensor configured to detect an electric field produced by the connecting bar, and a first electric screen comprising a second layer of electrically conductive material disposed on the outer surface of the support member. The body also includes a second section having a second electric screen comprising a third layer of electrically conductive material, and a third section including a third electric screen comprising a fourth layer of electrically conductive material. The sensor assembly also includes a dielectric material at least partially enclosing the body. The first section is disposed between the second section and the third section along the longitudinal axis, and the first layer, the second layer, the third layer, and the fourth layer are electrically isolated from one another.

Other features and aspects of the disclosure will become apparent by consideration of the following detailed description and accompanying drawings.

### BRIEF DESCRIPTION OF THE DRAWINGS

FIG. 1 is a schematic view of a first embodiment of a sensor assembly according to the present disclosure;

FIG. 1A is a schematic view of a tubular body in the embodiment in FIG. 1, laid flat;

FIG. 2 is a schematic view of a second embodiment of a sensor assembly according to the present disclosure;

FIG. 2A is a schematic view of a tubular body in the embodiment in FIG. 2, laid flat;

FIG. 3 is a schematic view of a third embodiment of a sensor assembly according to the present disclosure;

FIG. 3A is a schematic view of a tubular body in the embodiment in FIG. 3, laid flat;

FIG. 4 is a schematic view of a fourth embodiment of a sensor assembly according to the present disclosure;

FIG. 4A is a schematic view of a tubular body in the embodiment in FIG. 4, laid flat;

FIG. 5 is a schematic view of a fifth embodiment of a sensor assembly according to the present disclosure;

FIG. 5A is a schematic view of a tubular body in the embodiment in FIG. 5, laid flat.

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Also, it is to be understood that the phraseology and terminology used herein is for the purpose of description and should not be regarded as limiting.

### DETAILED DESCRIPTION

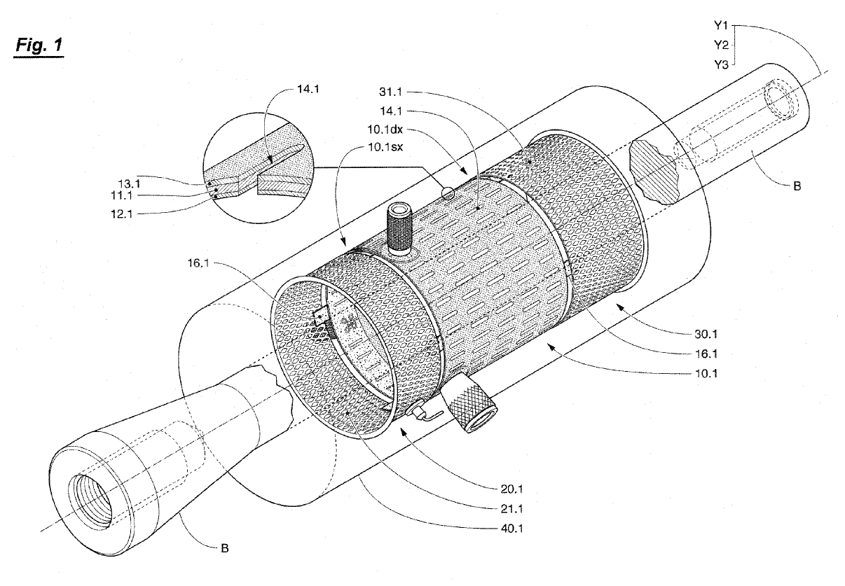

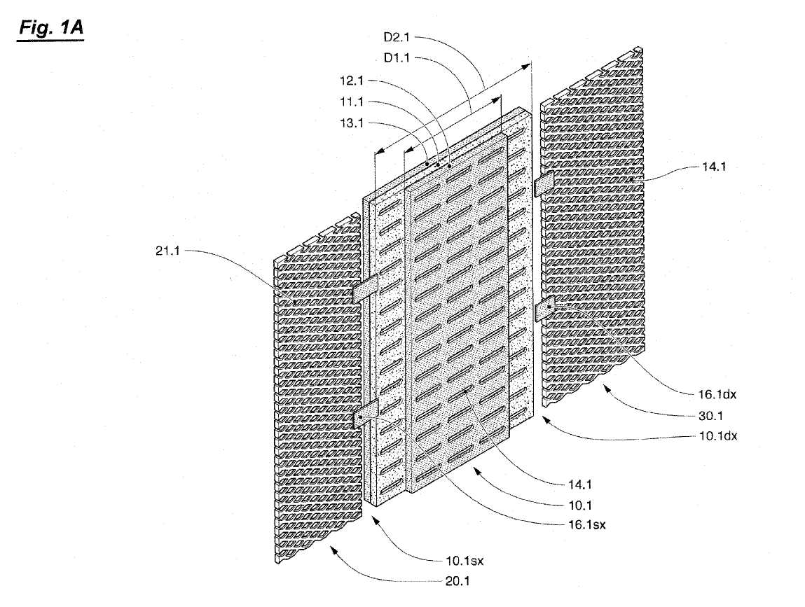

With reference to attached FIGS. 1 to 5A, a sensor assembly according to embodiments of the present disclosure extends along a first longitudinal axis Y1 and includes a connecting bar B extending longitudinally along a respective second longitudinal axis Y2; a tubular body extending longitudinally along a third longitudinal axis Y3; a mass of dielectric material 40.1/40.2/40.3/40.4/40.5 designed to at least partially enclose the components of the sensor assembly, in which said tubular body is positioned coaxially about said connecting bar B and is spaced radially apart from said central connecting bar B.

Again with reference to attached FIGS. 1 to 5A, said tubular body has a first tubular section 10.1/10.2/10.3/10.4/10.5, which in the illustrated embodiments includes: a first self-supporting tubular laminar element or support member 11.1/11.2/11.3/11.4/11.5 made of insulating material; a first thin layer of electrically conductive material 12.1/12.2/12.3/12.4/12.5 applied to one or more inner faces of said first self-supporting tubular laminar element 11.1/11.2/11.3/11.4/11.5; and a second thin layer of electrically conductive material 13.1/13.2/13.3/13.4/13.5 applied to one or more outer faces of said first self-supporting tubular laminar element 11.1/11.2/11.3/11.4/11.5.

The first self-supporting tubular laminar element 11.1/11.2/11.3/11.4/11.5 may perform the function of a supporting structure and, more specifically, the function of a tubular element not liable to suffer from deformation when casting resin and providing support using layers of conductive material.

The first thin layer of electrically conductive material 12.1/12.2/12.3/12.4/12.5 may function as an electric field sensor and, more specifically, is able to form a first electrode for a capacitive coupling with the central bar B as second electrode.

The second thin layer of electrically conductive material 13.1/13.2/13.3/13.4/13.5 may function as an electric screen and, more specifically, by connection to ground or to a known potential, an electric screen able to screen or shield the electric field sensor formed by the first thin layer of electrically conductive material 12.1/12.2/12.3/12.4/12.5 from external electrical fields or interference.

The tubular body of the sensor assembly can also include a second tubular section 20.1/20.2/20.3/20.4/20.5; in which said second tubular section 20.1/20.2/20.3/20.4/20.5 is positioned axially beside a first axial end (10sx) of the first tubular section 10.1/10.2/10.3/10.4/10.5; in which said second tubular section 20.1/20.2/20.3/20.4/20.5 may function as an electric screen, by connecting to ground or to a reference potential, as explained below.

Furthermore, the tubular body of the sensor assembly can also include a third tubular section 30.1/30.2/30.3/30.4/30.5; in which said third tubular section (30.1/30.2/30.3/30.4/30.5) is positioned axially beside a second axial end 10dx of the first tubular section 10.1/10.2/10.3/10.4/10.5; in which said third tubular section 30.1/30.2/30.3/30.4/30.5 may function as an electric screen, by connecting to ground or to a reference potential.

Said second tubular section 20.1/20.2/20.3/20.4/20.5 and/or said third tubular section 30.1/30.2/30.3/30.4/30.5 can also perform the function of an electric field sensor in order to detect the presence or absence of voltage on the connecting bar B.

The second tubular section 20.1/20.2/20.3/20.4/20.5 and/or said third tubular section 30.1/30.2/30.3/30.4/30.5 are associated with and/or linked to said first tubular section 10.1/10.2/10.3/10.4/10.5. Preferably, said first tubular section 10.1/10.2/10.3/10.4/10.5 and/or said second tubular section 20.1/20.2/20.3/20.4/20.5 and/or said third tubular section 30.1/30.2/30.3/30.4/30.5 includes one or more through-openings 14.1/14.2/14.3/14.4/14.5/21.1/21.2/21.3/21.4/21.4/31.1/31.2/31.3/31.4/31.5, which are wide enough to enable a resin of dielectric material in liquid/paste state to pass through said first through-openings 14.1/14.2/14.3/14.4/14.5; 21.1/21.2/21.3/21.4/21.5; 31.1/31.2/31.3/31.4/31.4/31.5.

With reference to FIGS. 1 and 1A, said first tubular section 10.1 can be made using a conductive double-sided Vetronite board (for example a copper double-sided Vetronite board-PCB) including a self-supporting lamina of insulating material 11.1 able to perform the support function, a first thin inner layer 12.1 of electrically conductive material detached from other layers of conductive material applied to said self-supporting lamina of insulating material 11.1 and a first thin outer layer 13.1 of conductive material applied to said self-supporting lamina of insulating material 11.1; in which the first thin inner layer 12.1 may function as an electric field sensor, i.e. to form a capacitive coupling with the bar B; and in which the first thin outer layer 13.1 may function as an electric screen, for example by means of a connection to ground.

Preferably, the first thin inner layer 12.1 of conductive material has an axial length D1.1 that is less than the axial length D2.1 of the first thin outer layer 13.1 of conductive material, preferably but without limitation as shown in FIG. 1A.

With reference to the aforementioned structural description, said first tubular section 10.1 may be made using a single conductive double-sided Vetronite board (for example a copper double-sided Vetronite board-PCB), for example etched by photoengraving or mechanical milling and wrapped into a tube shape.

Again with reference to FIGS. 1 and 1A, said second tubular section 20.1 and/or said third tubular section 30.1 can be made from a wire mesh, preferably electrically disconnected from other conductive elements, in which said wire mesh can be connected to ground in order to perform the function as an electric screen, and in which, where desired, said wire mesh can form a capacitive coupling with the bar B to detect the presence or absence of voltage on said bar B.

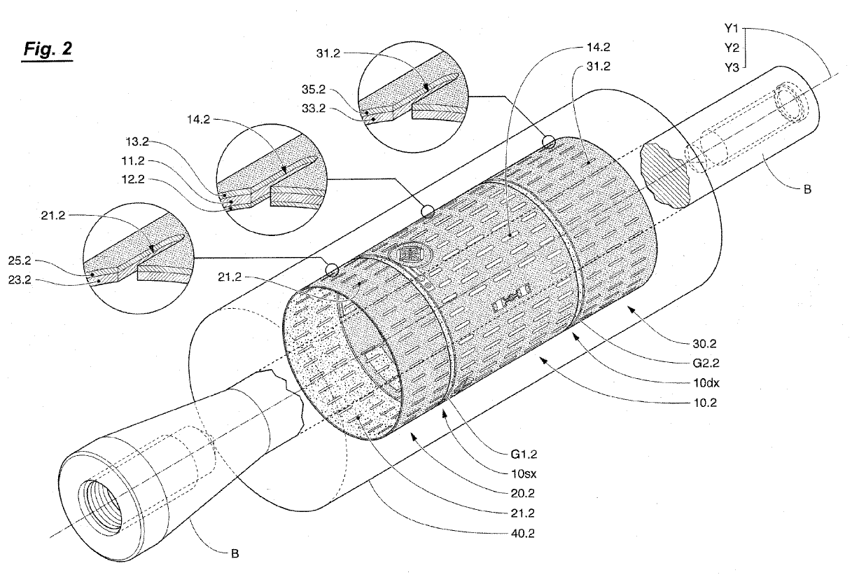

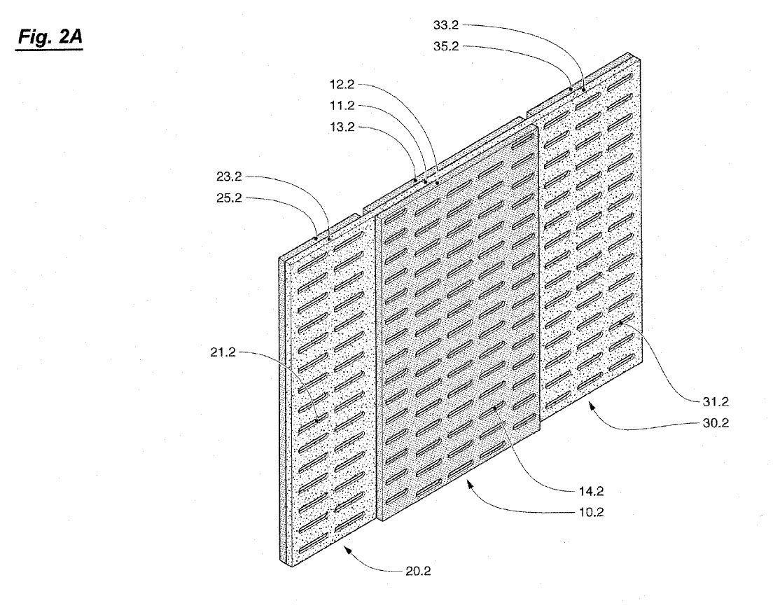

With reference to FIGS. 2 and 2A, said sensor assembly, and more specifically said tubular body including said first, second and third tubular sections 20.2/10.2/30.2, can include: a self-supporting lamina of insulating material 23.2/11.2/33.2 able to perform the support function; a first thin inner layer 12.2 of electrically conductive material applied to said self-supporting lamina of insulating material 23.2/11.2/33.2 and electrically disconnected from the other layers of conductive material; a first thin outer layer 25.2 of conductive material applied to said self-supporting lamina of insulating material 23.2/11.2/33.2; a second thin outer layer 13.2 of conductive material applied to said self-supporting lamina of insulating material 23.2/11.2/33.2; a third thin outer layer 35.2 of conductive material applied to said self-supporting lamina of insulating material 23.2/11.2/33.2, in which said layers have specific axial lengths, preferably but without limitation as shown in FIG. 2A.

The first thin inner layer 12.2 may function as an electric field sensor, i.e. to form a capacitive coupling with the bar B; the first thin outer layer 25.2 may function as an electric screen, for example by connection to ground, and/or the function of detecting the presence or absence of voltage on the bar B; the second thin outer layer 13.2 may function as an electric screen, for example by means of a connection to ground; the third thin outer layer 35.2 may function as an electric screen, for example by means of a connection to ground; and/or the function of detecting the presence or absence of voltage on the bar B.

Preferably, with reference to the aforementioned structural description, said first tubular section 10.2, said second tubular section 20.2 and said third tubular section 30.2 are made using a single conductive double-sided Vetronite board (for example a copper double-sided Vetronite board-PCB), for example etched by photoengraving or mechanical milling and wrapped into a tube shape.

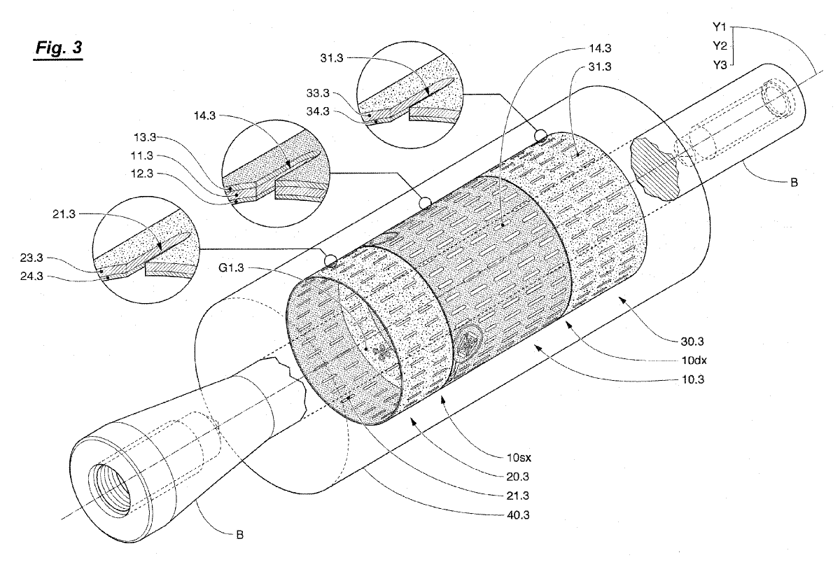

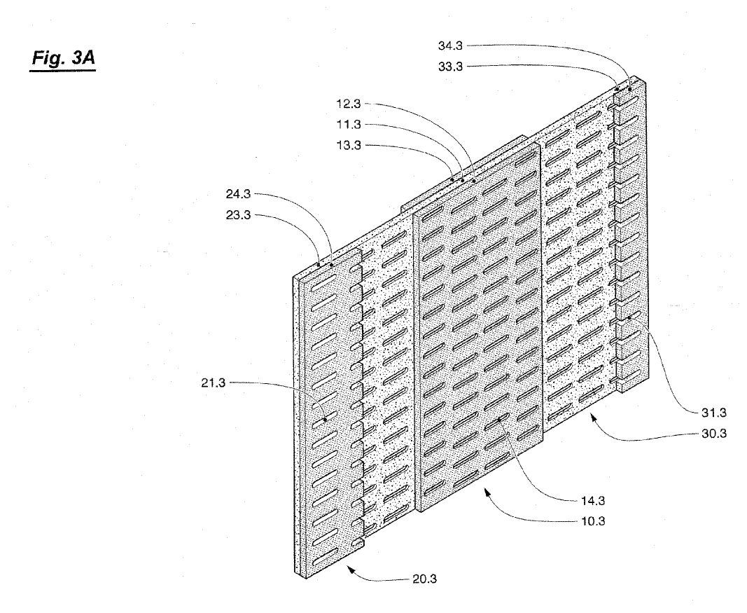

With reference to FIGS. 3 and 3A, said sensor assembly, and more specifically said tubular body including said first, second and third tubular sections 20.3/10.3/30.3, can include: a self-supporting lamina of insulating material 23.3/11.3/33.3 able to perform the function of support lamina; a first thin inner layer 24.3 of conductive material applied to said self-supporting lamina of insulating material 23.3/11.3/33.3; a second thin inner layer 12.3 of conductive material applied to said self-supporting lamina of insulating material 23.3/11.3/33.3 and electrically disconnected from the other layers of conductive material; a third thin inner layer 34.3 of conductive material applied to said self-supporting lamina of insulating material 23.3/11.3/33.3; a first thin outer layer 13.3 of conductive material applied to said self-supporting lamina of insulating material 23.3/11.3/33.3; in which said layers have specific axial lengths, preferably but without limitation as shown in FIG. 3A.

The first thin inner layer 24.3 may function as an electric screen, for example by connection to ground, and/or the function of detecting the presence or absence of voltage on the bar B.

The second thin inner layer 12.3 may function as an electric field sensor, i.e. to form a capacitive coupling with the bar B.

The third thin inner layer 34.3 of conductive material may function as an electric screen, for example by connection to ground, and/or the function of detecting the presence or absence of voltage on the bar B.

The first thin outer layer 13.3 may function as an electric screen, for example by means of a connection to ground.

Preferably, with reference to the aforementioned structural description, said first tubular section 10.3, said second tubular section 20.3 and said third tubular section 30.3 are made using a single conductive double-sided Vetronite board (for example a copper double-sided Vetronite board-PCB), for example etched by photoengraving or mechanical milling and wrapped into a tube shape.

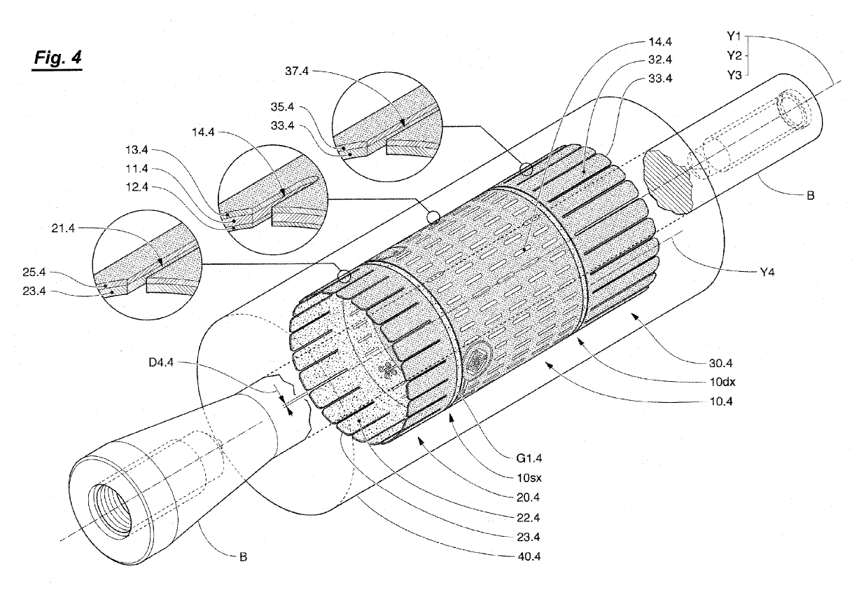

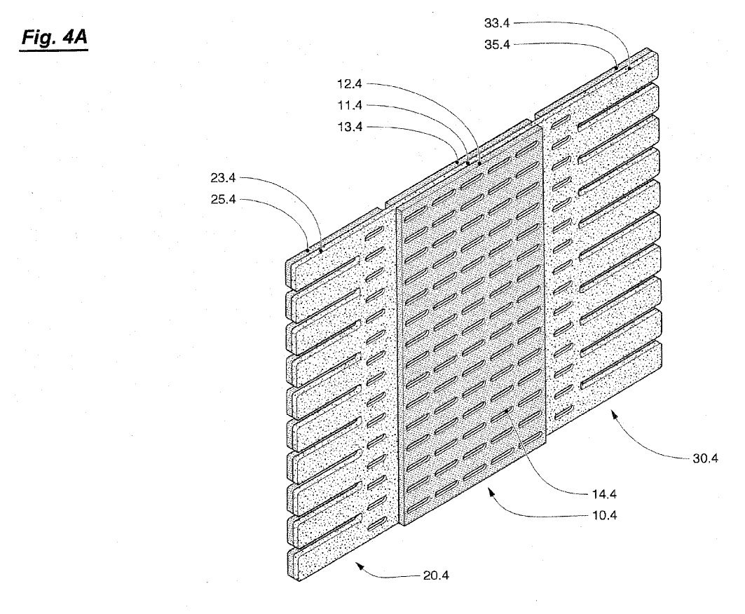

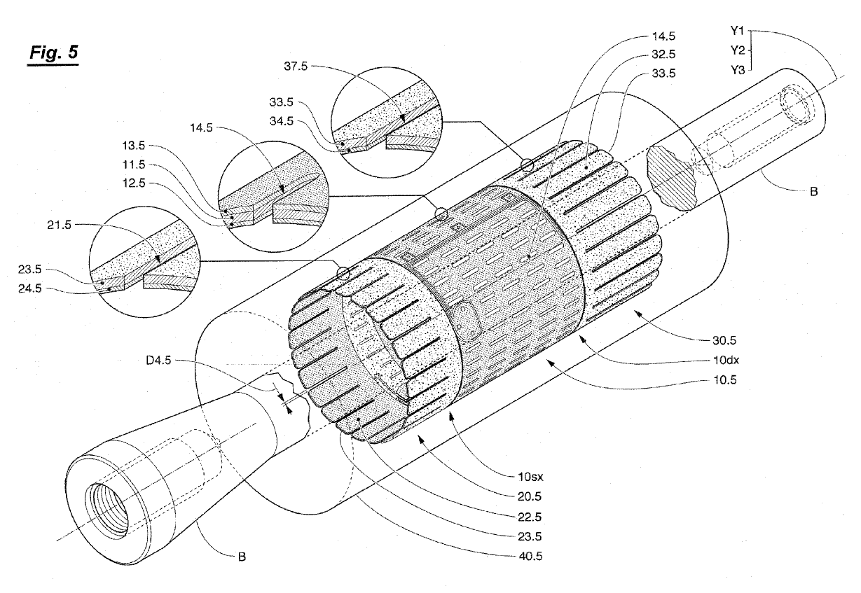

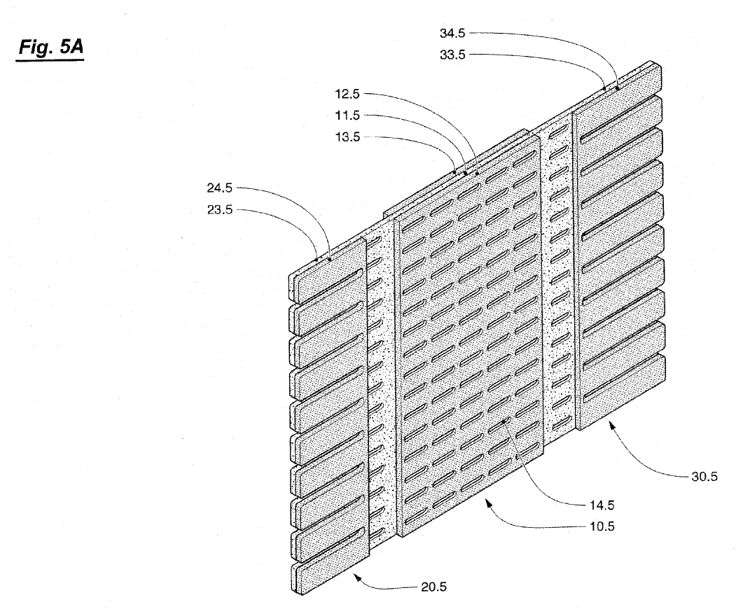

With reference to FIGS. 4-4A and 5-5A, the second tubular section 20.4/20.5 and/or said third tubular section 30.4/30.5 includes one or more cantilevered tabs 22.4, 32.4/22.5, 32.5.

More specifically, with reference to FIGS. 4-4A and 5-5A, the sensor assembly according to the present invention, in which said sensor assembly extends along a first longitudinal axis Y1, in which said sensor assembly comprises: a connecting bar B extending longitudinally along a respective second longitudinal axis Y2; a tubular body extending longitudinally along a third longitudinal axis Y3; a mass of dielectric material 40.4/40.5 designed to at least partially enclose the components of the sensor assembly; in which said tubular body is positioned coaxially about said connecting bar B; in which said tubular body is spaced apart radially from said central connecting bar B; has a tubular body with one or more cantilevered tabs 22.4, 32.4/22.5, 32.5.

Said tabs 22.4, 32.4/22.5, 32.5 are preferably oriented axially Y4 such that the free ends thereof 23.4, 33.4/23.5, 33.5 form at least one axial end of said tubular body, thereby forming crenelated axial ends.

Again preferably, two or more tabs 22.4/22.4, 32.4/32.4/22.5/22.5, 32.5/32.5, positioned side by side, are provided, in which the axial edge of a first tab 22.4, 32.4/22.5, 32.5 is spaced apart D4.4/D4.5 circumferentially from the axial edge of a second tab 22.4, 32.4/22.5, 32.5 positioned next to said first tab 22.4, 32.4/22.5, 32.5 in order to form axial through-openings 21.4/21.5.

Said through-openings 21.4 are wide enough to enable a resin of dielectric material in liquid/paste state to pass through said through-openings 21.4.

Again preferably, said tabs 22.4, 32.4/22.5, 32.5 are flexible and, more specifically, have a degree of flexibility selected in consideration of the shrinkage characteristics of the resin used in the casting, in order to enable said tabs to flex during the shrinkage phases of the resin that occur during solidification of said resin.

With reference to FIGS. 4 and 4A, said sensor assembly, and more specifically said tubular body including said first, second and third tubular sections 20.4/10.4/30.4, can include:

a self-supporting lamina of insulating material 23.4/11.4/33.4 able to perform the support function; a first thin inner layer 12.4 of electrically conductive material applied to said self-supporting lamina of insulating material 23.4/11.4/33.4 and electrically disconnected from the other layers of conductive material; a first thin outer layer 25.4 of conductive material applied to said self-supporting lamina of insulating material 23.4/11.4/33.4; a second thin outer layer 13.4 of conductive material applied to said self-supporting lamina of insulating material 23.4/11.4/33.4; a third thin outer layer 35.4 of conductive material applied to said self-supporting lamina of insulating material 23.4/11.4/33.4.

The first thin inner layer 12.4 may function as an electric field sensor, i.e. to form a capacitive coupling with the bar B.

The first thin outer layer 25.4 may function as an electric screen, for example by connection to ground, and/or the function of detecting the presence or absence of voltage on the bar B.

The second thin outer layer 13.4 may function as an electric screen, for example by means of a connection to ground.

The third thin outer layer 35.4 may function as an electric screen, for example by connection to ground, and/or the function of detecting the presence or absence of voltage on the bar B.

Preferably, with reference to the aforementioned structural description, said first tubular section 10.4, said second tubular section 20.4 and said third tubular section 30.4 are made using a single copper double-sided Vetronite board (PCB), for example etched by photoengraving or mechanical milling and wrapped into a tube shape.

With reference to FIGS. 5 and 5A, said sensor assembly, and more specifically said tubular body including said first, second and third tubular sections 20.5/10.5/30.5, can include: a self-supporting lamina of insulating material 23.5/11.5/33.5 able to perform the support function; a first thin outer layer 13.5 of conductive material applied to said self-supporting lamina of insulating material 23.5/11.5/33.5; a first thin inner layer 24.5 of conductive material applied to said self-supporting lamina of insulating material 23.5/11.5/33.5; a second thin inner layer 12.5 of conductive material applied to said self-supporting lamina of insulating material 23.5/11.5/33.5; and a third thin inner layer 34.5 of conductive material applied to said self-supporting lamina of insulating material 23.4/11.4/33.4.

The first thin outer layer 13.5 may function as an electric screen, for example by means of a connection to ground.

The first thin inner layer 24.5 may function as an electric screen, for example by connection to ground, and/or the function of detecting the presence or absence of voltage on the bar B.

The second thin inner layer 12.5 may function as an electric field sensor, i.e. to form a capacitive coupling with the bar B.

The third thin inner layer 34.5 may function as an electric screen, for example by connection to ground, and/or the function of detecting the presence or absence of voltage on the bar B.

Preferably, with reference to the aforementioned description, said first tubular section 10.5, said second tubular section 20.5 and said third tubular section 30.5 are made using a single copper double-sided Vetronite board (PCB), for example etched by photoengraving or mechanical milling and wrapped into a tube shape.

Although the disclosure has been described in detail with reference to certain preferred embodiments, variations and modifications exist within the scope and spirit of one or more independent aspects of the disclosure as described. In addition, some aspects of the present disclosure may include, but are not limited to:
Aspect 1. Sensor assembly regarding a through isolator, wherein said sensor assembly extends along a first longitudinal axis (Y1), wherein said sensor assembly comprises: a connecting bar (B) extending longitudinally along a respective second longitudinal axis (Y2); a tubular body extending longitudinally along a third longitudinal axis (Y3); a mass of dielectric material (4.1/40.2/40.3/40.4/40.5) able for incorporating at least partially the components of the sensor assembly; wherein said tubular body is positioned coaxially around said connecting bar (B); wherein said tubular body is radially spaced with respect to said central connecting bar (B); characterized by the fact that said tubular body comprises a first tubular section (10.1/10.2/10.3/10.4/10.5) comprising: a first self-supporting tubular laminar element (11.1/11.2/11.3/11.4/11.5) made of insulating material; a first thin layer of electrically conductive material (12.1/12.2/12.3/12.4/12.5) applied on one or more inner faces of said first self-supporting tubular laminar element (11.1/11.2/11.3/11.4/11.5); a second thin layer of electrically conductive material (13.1/13.2/13.3/13.4/13.5) applied on one or more external faces of said first self-supporting tubular laminar element (11.1/11.2/11.3/11.4/11.5); by the fact that said first self supporting tubular laminar element (11.1/11.2/11.3/11.4/11.5) is able to perform the function of supporting structure; by the fact that said first thin layer of electrically conductive material (12.1/12.2/12.3/12.4/12.5) is able to perform the function of an electric field sensor; by the fact that said second thin layer of electrically conductive material (13.1/13.2/13.3/13.4/13.5) is able to perform the function of an electric screen; by the fact to further comprising a second tubular section (20.1/20.2/20.3/20.4/20.5); by the fact that said second tubular section (20.1/20.2/20.3/20.4/20.5) is positioned axially at the side of a first axial end (10sx) of the first tubular section (10.1/10.2/10.3/10.4/10.5); and by the fact that said second tubular section (20.1/20.2/20.3/20.4/20.5) is able to perform the function of electric screen.
Aspect 2. Sensor assembly according to aspect 1, characterized by the fact that it further comprises a third tubular section (30.1/30.2/30.3/30.4/30.5); by the fact that said third tubular section (30.1/30.2/30.3/30.4/30.5) is positioned axially at the side of a second axial end (10dx) of the first tubular section (10.1/10.2/10.3/10.4/10.5); and by the fact that said third tubular section (30.1/30.2/30.3/30.4/30.5) is able to perform the function of electric screen.
Aspect 3. Sensor assembly according to aspect 1 or 2, characterized by the fact that said first tubular section (10.1) is made by means of a double-sided plain copper PCB and by the fact that said second tubular section (20.1) and/or said third tubular section (30.1) are made of a wire mesh.
Aspect 4. Sensor assembly according to one of aspects 1 to 3, characterized in that it comprises: a self-supporting lamina of insulating material (23.2/11.2/33.2) suitable for carrying out the support function; a first thin inner layer (12.2) of conductive material applied to said self-supporting lamina of insulating material (23.2/11.2/33.2) and electrically disconnected with respect the other layers of conductive material; a first thin outer layer (25.2) of conductive material applied to said self-supporting lamina of insulating material (23.2/11.2/33.2); a second thin outer layer (13.2) of conductive material applied to said self-supporting lamina of insulating material (23.2/11.2/33.2); and a third thin outer layer (35.2) of conductive material applied to said self-supporting lamina of insulating material (23.2/11.2/33.2) and by the fact that the first thin inner layer (12.2) is able to perform the function of sensor of the electric field generated by the connecting bar (B), the first thin outer layer (25.2) is able to perform the function of an electric screen, the second thin outer layer (13.2) is suitable to perform the function of an electric screen; and the third thin outer layer (35.2) is adapted to perform the function of an electric screen.
Aspect 5. Sensor assembly according to aspect 4, characterized by the fact that said first tubular section (10.2) said second tubular section (20.2) and said third tubular section (30.2) are made by means of a double-sided plain copper PCB.
Aspect 6. Sensor assembly according to aspect 1 or 2, characterized by the fact that it comprises: a self-supporting foil of insulating material (23.3/11.3/33.3) suitable for carrying out the supporting foil function; a first thin inner layer (24.3) of conductive material applied to said self-supporting lamina of insulating material (23.3/11.3/33.3); a second thin inner layer (12.3) of conductive material applied to said self-supporting lamina of insulating material (23.3/11.3/33.3) and electrically disconnected from the other layers of conductive material; a third thin inner layer (33.3) of conductive material applied to said self-supporting lamina of insulating material (23.3/11.3/33.3); a first thin outer layer (13.3) of conductive material applied to said self-supporting lamina of insulating material (23.3/11.3/33.3); and by the fact that the first thin inner layer (24.3) is able to perform the function of an electric screen, the second thin inner layer (12.3) is able to perform the function of sensor of the electric field generated by the connecting bar (B), the third thin inner layer (34.3) is able to perform the function of an electric screen, the first thin outer layer (13.3) is able to perform the function of an electric screen.
Aspect 7. Sensor assembly according to aspect 6, characterized by the fact that said first tubular section (10.3) said second tubular section (20.3) and said third tubular section (30.3) are made by means of double-sided plain copper PCB.
Aspect 8. Sensor assembly according to any one of aspects 1 to 7, characterized by the fact that said second tubular section (20.4/20.5) and/or said third tubular section (30.4/30.5) comprises one or more tabs (22.4, 32.4/22.5, 32.5) supported in an by cantilever manner.
Aspect 9. Sensor assembly regarding a through isolator, wherein said sensor assembly extends along a first longitudinal axis (Y1), wherein said sensor assembly comprises: a connecting bar (B) extending longitudinally along a respective second longitudinal axis (Y2); a tubular body extending longitudinally along a third longitudinal axis (Y3); a mass of dielectric material (40.4/40.5) able for incorporating at least partially the components of the sensor assembly; wherein said tubular body is positioned coaxially around said connecting bar (B); wherein said tubular body is radially spaced with respect to said central connecting bar (B); characterized by the fact that said tubular body comprises one or more tabs (22.4, 32.4/22.5, 32.5) supported in a cantilever manner.
Aspect 10. Sensor assembly according to aspect 8 or 9, characterized by the fact that said tabs (22.4, 32.4/22.5, 32.5) are axially oriented (Y4) in order to configure with their free ends (23.4, 33.4/23.5, 33.5) at least one axial end of the tubular body.
Aspect 11. Sensor assembly according to aspect 8, 9 or 10, characterized by the fact to comprises two or more tabs (22.4/22.4, 32.4/32.4/22.5/22.5, 32.5/32.5) positioned side by side.
Aspect 12. Sensor assembly according to aspect 11, characterized by the fact that the axial edge of a first tab (22.4, 32.4/22.5, 32.5) is circumferentially spaced (D4.4/D4.5) with respect to the axial edge of a second tab (22.4, 32.4/22.5, 32.5) positioned next to said first tab (22.4, 32.4/22.5, 32.5) in order to form axial through openings (21.4/21.5).
Aspect 13. Sensor assembly according to one of the aspects from 8 to 12, characterized by the fact that said tabs (22.4, 32.4/22.5, 32.5) are flexible.
Aspect 14. Sensor assembly according to one of the aspects from 1 to 13, characterized by the fact that at least one axial end of said tubular body has the shape.
Aspect 15. Sensor assembly according to one of the aspects from 8 to 14, characterized by the fact that it comprises: a self-supporting foil of insulating material (23.4/11.4/33.4) able for carrying out the support function; a first thin inner layer (12.4) of conductive material electrically applied to said self-supporting lamina of insulating material (23.4/11.4/33.4) and disconnected from the other layers of conductive material; a first thin outer layer (25.4) of conductive material applied to said self-supporting lamina of insulating material (23.4/11.4/33.4); a second thin outer layer (13.4) of conductive material applied to said self-supporting lamina of insulating material (23.4/11.4/33.4); a third thin outer layer (35.4) of conductive material applied to said self-supporting lamina of insulating material (23.4/11.4/33.4); and by the fact that the first thin inner layer (12.4) is able to detect the electric field generated by the connecting rod (B), the first thin outer layer (25.4) is able to perform the function of an electric screen, the second thin outer layer (13.4) is able to perform the function of an electric screen, the third thin outer layer (35.4) is able to perform the function of an electric screen.
Aspect 16. Sensor assembly according to aspect 15, characterized by the fact that said first tubular section (10.4) said second tubular section (20.4) and said third tubular section (30.4) are made by are made by means of a double-sided plain copper PCB.
Aspect 17. Sensor assembly according to one of the aspects from 8 to 24, characterized by the fact that it comprises: a self-supporting foil of insulating material (23.5/11.5/33.5) suitable for carrying out the support function; a first thin outer layer (13.5) of conductive material applied to said self-supporting lamina of insulating material (23.5/11.5/33.5); a first thin inner layer (24.5) of conductive material applied to said self-supporting lamina of insulating material (23.5/11.5/33.5); a second thin inner layer (12.5) of conductive material applied to said self-supporting lamina of insulating material (23.5/11.5/33.5); a third thin inner layer (34.5) of conductive material applied to said self-supporting lamina of insulating material (23.4/11.4/33.4); and by the fact that the first thin outer layer (13.5) is able to perform the function of an electric screen, the first thin inner layer (24.5) is able to perform the function of an electric screen, the second thin inner layer (12.5) is able to perform the electric field generated by the connecting bar (B), the third thin inner layer (34.5) is able to perform the function of an electric screen.
Aspect 18. Sensor assembly according to aspect 17, characterized by the fact that said first tubular section (10.5) said second tubular section (20.5) and said third tubular section (30.5) are made by a double-sided plain copper PCB.

Various features of the disclosure are set forth in the following claims.

What is claimed is:

1. A sensor assembly comprising:
an electrode extending along a longitudinal axis;
a tubular section extending along the longitudinal axis and at least partially surrounding the electrode such that the tubular section is radially spaced from the electrode; and
a mass of dielectric material extending along the longitudinal axis,
wherein the tubular section includes
a tubular support member comprising electrically insulating material, the tubular support member having a first dimension extending along the longitudinal axis, wherein the tubular support member at least partially surrounds the electrode such that the tubular support member is radially spaced from the electrode,
an inner electrically conductive material disposed on an inner surface of the support member, wherein the inner electrically conductive material has a second dimension extending along the longitudinal axis, and wherein the inner electrically conductive material is configured as an electric field sensor to form a capacitive coupling with the electrode;
a first tubular electric screen disposed on an outer surface of the support member, wherein the first tubular electric screen has a third dimension extending along the longitudinal axis and is electrically isolated from the inner electrically conductive material; and
a second tubular electric screen extending in a direction along the longitudinal axis beyond an axial end of the tubular support member, and wherein the second tubular electric screen is electrically isolated from the inner electrically conductive material,
wherein the mass of dielectric material at least partially encloses the electrode and the tubular support member, the inner electrically conductive material, and the first and second tubular electric screens.

2. The sensor assembly of claim 1, wherein the second tubular electric screen is configured as metal mesh.

3. The sensor assembly of claim 1, wherein the second tubular electric screen is configured as wire mesh.

4. The sensor assembly of claim 1, wherein the first dimension is greater than the second dimension.

5. The sensor assembly of claim 4, wherein the third dimension is greater than the second dimension.

6. The sensor assembly of claim 1, wherein the first tubular electric screen at least partially surrounds the electrode and the inner electrically conductive material such that the first tubular electric screen is radially spaced from the electrode and extends in an axial direction beyond an axial end of the inner electrically conductive material, and wherein the second tubular electric screen at least partially surrounds the electrode such that the second tubular electric screen is radially spaced from the electrode.

7. The sensor assembly of claim 1, wherein the tubular support member includes a plurality of interconnected sections, each section of the plurality of interconnected sections circumferentially separated from an adjacent section to define a through opening therebetween, and wherein each section of the plurality of interconnected sections extends in an axial direction outwardly from a center of the tubular support member, wherein each through opening is configured to enable the mass of dielectric material to pass through during casting.

8. The sensor assembly of claim 7, wherein the tubular section includes a flexible printed circuit board wrapped into a tube shape.

9. The sensor assembly of claim 8, wherein the plurality of interconnected sections is configured to flex during curing of the mass of dielectric material.

10. The sensor assembly of claim 7, wherein the plurality of interconnected sections is a first plurality of interconnected sections, each section of the first plurality of interconnected sections extending in a first axial direction outwardly from the center of the tubular electrically insulating member, and further comprising a second plurality of interconnected sections, each section of the second plurality of interconnected sections circumferentially separated from an adjacent section to define a through opening therebetween, and wherein each section of the second plurality of interconnected sections extends in a second axial direction outwardly from the center of the tubular electrically insulating member opposite the first direction.

11. A sensor assembly comprising:
a first electrode extending along a longitudinal axis;
a tubular second electrode at least partially surrounding the first electrode such that the tubular second electrode is radially spaced from the first electrode, wherein the tubular second electrode is configured to form a capacitive coupling with the first electrode as an electric field sensor;
a first tubular electric screen extending along the longitudinal axis, wherein the first tubular electric screen at least partially surrounds the tubular second electrode such that the tubular electric screen is radially spaced from the tubular second electrode and electrically isolated from the tubular second electrode;
a second tubular electric screen, wherein the second tubular electric screen at least partially surrounds the first electrode such that the tubular second electric screen is radially spaced from the first electrode, wherein the second tubular electric screen extends in an axial direction beyond an axial end of the second tubular electrode; and
a mass of dielectric material extending along the longitudinal axis and at least partially enclosing the electrode, the tubular second electrode, and the first and second tubular electric screens,
wherein the second tubular electric screen includes a plurality of through openings, each through opening configured to enable the mass of dielectric material to pass through during casting.

12. The sensor assembly of claim 11, wherein the second tubular electric screen is configured as a mesh.

13. The sensor assembly of claim 11, wherein the tubular second electrode includes an insulating material and inner electrically conductive material disposed inside of the insulating material and configured to form a capacitive coupling with the first electrode.

14. The sensor assembly of claim 11, wherein the tubular second electrode includes a plurality of through openings, each through opening of the plurality of through openings circumferentially separated from an adjacent through opening, and wherein each through opening of the plurality of through openings is configured to enable the mass of dielectric material to pass through during casting.

15. The sensor assembly of claim 11, wherein the first tubular electric screen extends in an axial direction beyond an axial end of the tubular second electrode.

16. A sensor assembly comprising:
a source electrode extending along a longitudinal axis;
a tubular section extending along the longitudinal axis and at least partially surrounding the source electrode such that the tubular section is radially spaced from the source electrode, the tubular section including:
a central portion including a first electrically conductive material configured to form a capacitive coupling with the source electrode,
a first axial end portion extending in a first direction away from the central portion along the longitudinal axis and including a second electrically conductive material electrically isolated from the first electrically conductive material, wherein the second electrically conductive material is configured to shield the capacitive coupling from external electric fields, and
a second axial end portion extending in a second direction opposite the first direction away from the central portion along the longitudinal axis and including a third electrically conductive material electrically isolated from the first electrically conductive material, wherein the third electrically conductive material is configured to shield the capacitive coupling from external electric fields; and
a mass of insulating material at least partially enclosing the source electrode and the tubular section, and
wherein each of the central portion, the first axial end portion, and the second axial end portion includes a plurality of through openings that are configured to be filled by the insulating material.

17. The sensor assembly of claim 16, wherein the source electrode extends beyond the first axial end portion and the second axial end portion of the tubular section.

18. The sensor assembly of claim 16, wherein the second electrically conductive material and the third electrically conductive material are electrically isolated from each other.

19. The sensor assembly of claim 16, wherein through openings of the plurality of through openings are configured as slits that extend in a direction along the longitudinal axis.

20. The sensor assembly of claim 16, wherein each through opening of the plurality of through openings is configured as a slit that extends in a direction along the longitudinal axis.

21. The sensor assembly of claim 16, wherein each of the central portion, the first axial end portion, and the second axial end portion includes electrically insulating material.

22. The sensor assembly of claim 16, wherein electrically insulating material is provided between the first axial end portion and the central portion and between the second axial end portion and the central portion.

23. A sensor assembly comprising:
a source electrode extending along a longitudinal axis;
a circular member at least partially surrounding the source electrode such that the circular member is radially spaced from the source electrode, wherein the circular member is multilayered including two layers of electrically conductive material;
a plurality of cantilevered sections extending from the circular member, wherein the plurality of cantilevered sections are located side by side in a circumferential manner around the longitudinal axis, wherein adjacent cantilevered sections of the plurality of cantilevered sections are spaced apart from each other in a circumferential manner around the longitudinal axis, and wherein each section of the plurality of cantilevered sections is multilayered; and
a mass of insulating material at least partially enclosing the source electrode and the plurality of cantilevered sections;
wherein spaces between adjacent cantilevered sections of the plurality of cantilevered sections are filled by the mass of insulating material, and wherein the spaces extend along the longitudinal axis.

24. The sensor assembly of claim 23, wherein each cantilevered section of the plurality of cantilevered sections includes an electrically conductive material configured to form a capacitive coupling with the source electrode or configured to function as an electric screen.

25. The sensor assembly of claim 23, wherein each cantilevered section includes electrically insulating material, wherein the spaces are configured as elongated slits that extend in a direction along the longitudinal axis, and wherein the source electrode extends through the plurality of cantilevered sections.
